(19) United States
(12) Patent Application Publication
(10) Pub. No.: US 2024/0413057 A1
(43) Pub. Date: Dec. 12, 2024

(54) SEMICONDUCTOR PACKAGE AND ULTRASOUND SYSTEM HAVING SAME

(71) Applicant: Infineon Technologies AG, Neubiberg (DE)

(72) Inventors: Horst THEUSS, Wenzenbach (DE); Klaus ELIAN, Alteglofsheim (DE)

(21) Appl. No.: 18/677,492

(22) Filed: May 29, 2024

(30) Foreign Application Priority Data
Jun. 9, 2023 (DE) 102023205370.5

(51) Int. Cl. H01L 23/495; H01L 23/02; H01L 23/498

(52) U.S. Cl. CPC H01L 23/49541; H01L 23/02; H01L 23/4985

(57) ABSTRACT

A semiconductor package is proposed. The semiconductor package includes a housing and at least one micromechanical ultrasonic transducer arranged in the housing. Furthermore, the semiconductor package includes a cable interface integrated into the housing, which is configured to be separably connected to a plug connector in order to electrically contact the semiconductor package externally.

### CROSS-REFERENCE TO RELATED APPLICATION

This application claims priority to German Patent Application No. 102023205370.5 filed on Jun. 9, 2023, the content of which is incorporated by reference herein in its entirety.

### TECHNICAL FIELD

The present disclosure relates to the contacting of semiconductor packages for ultrasound applications. In particular, examples relate to a semiconductor package and an ultrasound system having same

### BACKGROUND

One challenge in ultrasonic sensors is to ensure a good acoustic connection between the component and the surrounding system with the aid of coupling media. The simplest possible electrical connection of the acoustic sensors is also required.

There is therefore a need to enable an improved electrical connection of ultrasonic sensors.

### SUMMARY

This object is achieved by a semiconductor package and an ultrasound system as claimed in the independent claims. Further aspects and refinements are described in the dependent claims, the following description, and the figures.

According to a first aspect, the present disclosure relates to a semiconductor package. The semiconductor package includes a housing and at least one micromechanical ultrasonic transducer arranged in the housing. Furthermore, the semiconductor package includes a cable interface integrated into the housing, which is configured to be separably connected to a plug connector in order to electrically contact the semiconductor package externally.

According to a second aspect, the present disclosure relates to an ultrasound system. The ultrasound system includes a semiconductor package according to the first aspect and a cable having a plug connector. The plug connector is separably connectable to the cable interface integrated into the housing of the semiconductor package in order to electrically contact the semiconductor package using the cable.

The cable interface integrated into the housing of the semiconductor package is a compact solution for the flexible and simple installation of cables in order to electrically contact the at least one ultrasonic transducer. The semiconductor package or the at least one ultrasonic transducer can accordingly also be integrated into (very) small systems.

### BRIEF DESCRIPTION OF THE DRAWINGS

Some examples of devices and/or methods are explained in more detail below merely by way of example with reference to the accompanying figures. In the figures:

FIG. 1 schematically shows a first example of an ultrasound system having a semiconductor package;

FIG. 2 schematically shows a second example of an ultrasound system having a semiconductor package;

FIG. 3 schematically shows a third example of an ultrasound system having a semiconductor package;

FIG. 4 schematically shows a fourth example of an ultrasound system having a semiconductor package;

FIG. 5 schematically shows a fifth example of an ultrasound system having a semiconductor package;

FIG. 6 schematically shows a further semiconductor package;

FIG. 7 schematically shows a sixth example of an ultrasound system having a semiconductor package;

FIG. 8 schematically shows a seventh example of an ultrasound system having a semiconductor package; and

FIG. 9 schematically shows a rear view of the semiconductor package shown in FIG. 8.

### DETAILED DESCRIPTION

Some examples are now described in more detail with reference to the accompanying figures. Further possible examples are however not restricted to the features of these implementations that are described in detail. These may contain modifications of the features and equivalents and alternatives to the features. The terminology used herein to describe particular examples is also not intended to be restrictive for further possible examples.

The same or similar reference signs relate throughout the description of the figures to the same or similar elements or features, which may each be implemented identically or else in a modified form, while providing the same or a similar function. In the figures, the thicknesses of lines, layers and/or regions may also be exaggerated for clarification.

When two elements A and B are combined using an “or”, this is to be understood as meaning that all possible combinations are disclosed, e.g., only A, only B, and also A and B, unless expressly defined otherwise in the individual case. “At least one of A and B” or “A and/or B” may be used as alternative wording for the same combinations. This applies equivalently to combinations of more than two elements.

If a singular form, e.g., “a, an” and “the”, is used, and the use of only a single element is neither explicitly nor implicitly defined as mandatory, other examples may also use multiple elements to implement the same function. When a function is described in the following as being implemented using multiple elements, further examples may implement the same function using a single element or a single processing entity. Furthermore, it is understood that the terms “comprises”, “comprising”, “has” and/or “having” when used describe the presence of the indicated features, whole numbers, steps, operations, processes, elements, components and/or a group thereof, but do not thereby exclude the presence or the addition of one or more further features, whole numbers, steps, operations, processes, elements, components and/or a group thereof.

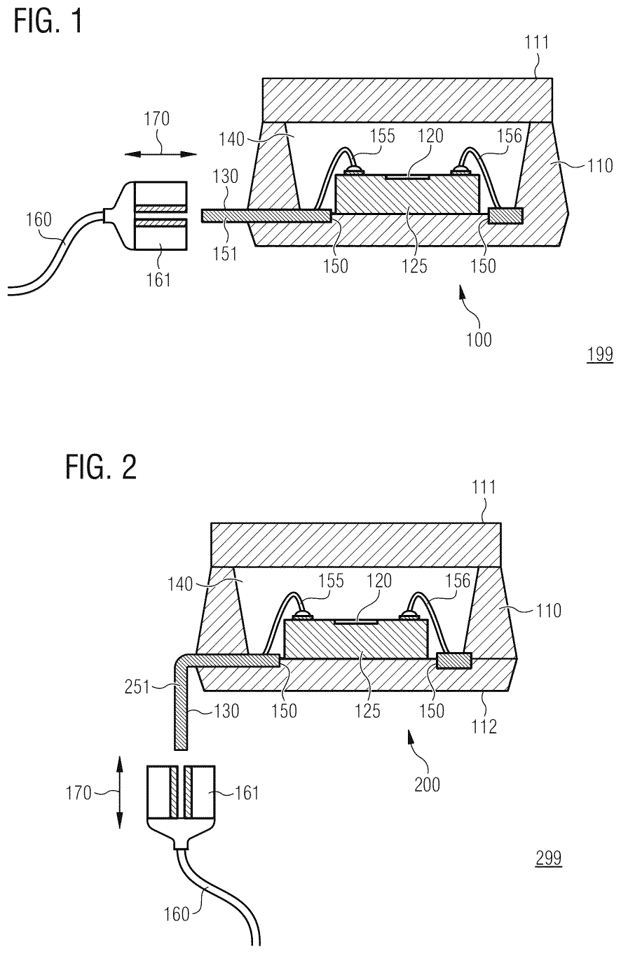

FIG. 1 schematically shows a sectional view of a first semiconductor package 100. The semiconductor package 100 comprises a housing 110. The housing 110 is formed from potting compound (potting material). For example, the potting compound can be an epoxy potting compound, a thermoplastic potting compound, such as polyphenylene sulfide (PPS), polystyrene (PS), polypropylene (PP), polycarbonate (PC), polybutylene succinate (PBS) or liquid crystal polymer (LCP), a thermoset potting compound, a foamed plastic potting compound, or a combination thereof. However, it is to be noted that the present disclosure is not restricted to the above-mentioned examples.

The semiconductor package 100 furthermore comprises at least one micromechanical ultrasonic transducer (micro-machined ultrasonic transducer, MUT) 120 arranged in the housing 110. An MUT is an ultrasonic transducer based on a microsystem (micro-electromechanical system, MEMS). The at least one MUT 120 is formed in a semiconductor material 125 such as a silicon die or silicon chip. However, it is to be noted that the present disclosure is not restricted to the above-mentioned semiconductor material. In principle, any suitable semiconductor material can be used. The semiconductor material 125 is arranged in the housing 110. The housing 110 is a physical package, which protects the at least one MUT and possibly further elements arranged in the housing. Precisely one MUT 120 is shown in FIG. 1. However, it is to be noted that the semiconductor package 100 is not restricted thereto. In general, the semiconductor package 100 can comprise an arbitrary number N≥1 of MUTs, which are packed (packaged, assembled, installed) in the housing 110. In other words: Optionally, multiple MUTs can also be arranged in the housing 110.

The MUT can be configured so that it detects ultrasonic waves received from the surroundings and/or generates ultrasonic waves and emits them to the surroundings. The energy transfer by the MUT can be based on various effects such as capacitance and piezoelectricity. In other words: An MUT, to which reference is made in the present disclosure, can be a capacitive micromechanical ultrasonic transducer (capacitive micro-machined ultrasonic transducer, CMUT) or a piezoelectric micromechanical ultrasonic transducer (piezoelectric micro-machined ultrasonic transducer, PMUT). A CMUT consists of two electrodes, wherein one of the electrodes is fixed and the other electrode is encapsulated, enclosed, or formed by a movable membrane of the MUT. The membrane electrode is separated from the fixed electrode by a small gas-filled gap (such as an air gap), so that the membrane electrode can move relative to the fixed electrode. A PMUT comprises a movable membrane, which is coupled with a piezoelectric element (device, structure) or is formed thereby. In general, the at least one MUT 120 can be configured so that it can emit and/or detect soundwaves at least between 20 kHz and 1 GHz and/or an arbitrary subrange thereof. In particular, the at least one MUT 120 can be configured so that it can emit and/or detect low-frequency ultrasonic waves (for example at approximately 50 kHz) for applications in the air such as proximity detection (for example for parking sensors of vehicles) or high-frequency ultrasonic waves (for example at approximately 2 to 10 MHz) for diagnostic applications (for example medical ultrasound).

Furthermore, at least one acoustic coupling medium 140 for acoustically coupling the at least one MUT 120 to the housing 110 is arranged (introduced) in the housing 110. As shown in FIG. 1, the acoustic coupling medium 140 can fill the housing 110. However, the housing 110 does not have to be completely filled with the acoustic coupling medium 140. The acoustic coupling medium 140 is a substance or a material which facilitates the transmission of ultrasonic waves between the housing 110 and the at least one MUT 120. The acoustic coupling medium 140 is used as a medium through which the ultrasonic waves can propagate to ensure that there is only the least possible or minimal energy loss when the ultrasonic waves pass from the at least one MUT 120 through the acoustic coupling medium 140 and into the housing 110 and vice versa. Moreover, the acoustic coupling medium 140 is a medium for impedance adaptation between the acoustic impedance of the at least one MUT 120 and the acoustic impedance of the housing 110. Accordingly, the acoustic impedance of the acoustic coupling medium 140 can be lower than an acoustic impedance of the at least one MUT 120. The acoustic impedance of the acoustic coupling medium 140 can also be higher than the acoustic impedance of the housing 110. The acoustic coupling medium 140 can be a gel, for example. However, the present disclosure is not restricted thereto. In other examples, the acoustic coupling medium 140 can be, for example, a cream or an oil. The acoustic coupling medium 140 can consist of various substances, such as silicone or b-stable epoxy. However, the present disclosure is not restricted to the above-mentioned substances. In general, any suitable substance can be used for the acoustic coupling medium 140. The composition of the acoustic coupling medium 140 can depend, for example, on the specific application and thus on the frequency range of the ultrasonic waves emitted and/or to be detected by the at least one MUT 120.

For example, the semiconductor package 100 can be attached to a first lateral surface 111 of the housing 110 or the semiconductor package 100 can be attached to an external application surface (not shown in FIG. 1). The external application surface is a surface outside the semiconductor package 100, to which the semiconductor package 100 can be attached (directly or indirectly). The external application surface is arranged between the semiconductor package 100, e.g., the at least one MUT 120, and an object (such as a finger or a hand) or spatial volume to be monitored or tracked. The external application surface can be, for example, a housing or a control panel of a device/an application which comprises the semiconductor package 100. For example, the external application surface can be the operating panel of a device of entertainment electronics or an operating panel of a vehicle (e.g., an automobile, a truck, a train, an aircraft, a ship, etc.) for touch inputs. Accordingly, the at least one MUT can be configured to emit ultrasonic waves in the direction of the first lateral surface 111 and/or receive ultrasonic waves through the first lateral surface 111. The ultrasonic waves can propagate through the coupling medium 140 with minimal energy loss between the at least one MUT 120 and the external application surface.

A lead frame (connection frame) 150 is arranged in the housing 110 and electrically coupled with the at least one MUT 120. For this purpose, the at least one MUT 120 is electrically contacted using one or more bond wires—as indicated in FIG. 1 by the bond wires 155 and 156 between the semiconductor material 125 and the lead frame 150. The electrical coupling with the lead frame 150 can be established via the one or more bond wires. Further electrical elements or components arranged in the housing 110 can be electrically coupled similarly via bond wires with the lead frame 150. The at least one MUT 120 can be electrically contacted via the lead frame 150.

At least one contact 151 of the lead frame 150 is led laterally out of the housing 110 in order to form a cable interface 130 integrated into the housing 110 in the form of a laterally extending electrical plug contact. The cable interface 130 or the at least one contact 151 of the lead frame 150 is configured to be separably connected to a plug connector 161 of a cable 160 in order to electrically contact or be able to electrically contact the semiconductor package 100 externally (from the outside). Precisely one contact 151 of the lead frame 150 is led out of the housing 110 in FIG. 1. However, it is to be noted that the semiconductor package 100 is not restricted thereto. In general, an arbitrary number M≥1 of contacts of the lead frame 150 can be led laterally out of the housing 110. In other words: Optionally, multiple contacts of the lead frame 150 can also be led laterally out of the housing 110 in order to form a respective laterally extending electrical plug contact for one or more plug connectors of one or more cables. As indicated by the arrow 170 in FIG. 1, the plug connector 161 of the cable 160 is separably connectable to the cable interface 130 integrated into the housing 110 of the semiconductor package 100, e.g., the at least one contact 151 of the lead frame 150, in order to electrically contact the semiconductor package 100 using the cable 160.

For example, one or more control signals for the at least one MUT 120 or other electrical elements or components in the housing 110 can be provided via the cable 160 or the cable interface 130 integrated into the housing 110. Similarly, one or more output signals of the at least one MUT 120 or other electrical elements or components in the housing 110 can be read out via the cable 160 or the cable interface 130 integrated into the housing 110. The semiconductor package 100 and the cable 160 form an ultrasound system 199.

The at least one MUT 120 can be operated as an ultrasonic emitter and/or as an ultrasonic receiver (detectors). In order to control a CMUT, for example, so that it emits ultrasonic waves, a DC voltage for the bias voltage of the electrodes and an AC voltage for actuating the membrane can be supplied (applied) to the electrodes of the CMUT. To control a CMUT which functions as an ultrasonic receiver (detector), a DC voltage for the bias voltage of the electrodes can be supplied (applied) to the electrodes of the CMUT and the voltage change between the electrodes, which is caused by the capacitance change due to the movement of the membrane by the received ultrasonic waves, can be measured. The signals or voltages to be applied to the CMUT can be provided via the cable 160 and applied to the CMUT via the lead frame 150. Similarly, the voltage change caused by the movement of the membrane between the electrodes of the CMUT can be led out of the semiconductor package 100 via the lead frame 150 (e.g., the cable interface 130) and supplied via the cable 160 to an external circuit for further processing. In a similar manner, to control a PMUT which emits ultrasonic waves, for example, an AC voltage can be supplied (applied) to the piezoelectric element in order to actuate the membrane by the induced deflection of the piezoelectric element. To control a PMUT which functions as an ultrasonic receiver (detector), for example, the voltage output by the piezoelectric element due to the deflection of the piezoelectric element by the received ultrasonic waves can be measured. The signals to be applied to the PMUT or the voltage to be applied can be provided via the cable 160 and applied via the lead frame 150 to the PMUT. Similarly, the piezoelectric voltage caused by the movement of the membrane can be led via the lead frame 150 out of the semiconductor package 100 and supplied via the cable 160 to an external circuit for further processing. In other words: The control of the at least one MUT 120 can take place externally via corresponding signals supplied via the cable 160 to the cable interface 130. One or more output signals of the at least one MUT 120 can also be supplied to an external circuit for further processing via the cable interface 130 or the cable 160.

In alternative examples, the control or readout of the at least one MUT 120 can also take place internally, e.g., inside the semiconductor package 100. For this purpose, the semiconductor package 100 can comprise, for example, a processor circuit (not shown in FIG. 1), which is electrically connected to the at least one MUT 120. The processor circuit can be formed in the semiconductor material 125 or a separate semiconductor material arranged in the housing 110, such as a further silicon die or silicon chip. The processor circuit can be electrically coupled, for example, with the lead frame 150. For this purpose, the processor circuit—similarly to the above statements for the at least one MUT 120—can be electrically contacted, for example, using one or more bond wires. The electrical coupling with the lead frame 150 can be established via the one or more bond wires. The processor circuit is configured to control the at least one MUT 120 and to process the output signal or signals of the at least one MUT 120. The control of the at least one MUT 120 or the processing of the output signal or signals of the at least one MUT 120 by the processor circuit can take place here according to the above statements for the external control or further processing. The processor circuit can be implemented in various ways. For example, the processor circuit can be or comprise an application-specific integrated circuit (ASIC), a field programmable gate array (FPGA), a processor, or a combination thereof. The processor circuit can optionally be coupled with a memory or comprise same, in which a program having a program code is stored which causes the processor circuit to carry out the functions described herein when the program is executed by the processor circuit. Accordingly, corresponding control commands or control signals for the processor circuit can be provided to the cable interface 130 via the cable 160. One or more output signals of the processor circuit can also be supplied to an external circuit for further processing via the cable interface 130 or the cable 160.

Optionally, the semiconductor package 100 can comprise further electronic components, e.g., one or more amplifiers for amplifying one or more signals within the semiconductor package 100, one or more passive electronic components (such as resistors, capacitors, or inductors), or one or more light-emitting diodes (LEDs) for status indication. Depending on the type, the further electronic components can be arranged in or on the housing.

In the example of FIG. 1, the at least one contact 151 of the lead frame 150 protrudes laterally out of the housing in order to form a respective laterally extending electrical plug contact as the cable interface 130. However, it is to be noted that the present disclosure is not restricted thereto.

FIG. 2 schematically shows a sectional view of a further semiconductor package 200 in which the at least one contact of the lead frame 150 led to the outside extends differently. Otherwise, the semiconductor package 200 is embodied like the semiconductor package 100. As in the semiconductor package 200, the contact 251 of the lead frame 150 initially also protrudes laterally out of the housing 110. In contrast to the contact 151, the contact 251 in the example of FIG. 2 is bent in the direction of a second lateral surface 112 of the housing 110 or the semiconductor package 200 in order to form an electrical plug contact as the cable interface 130. The second lateral surface 112 is opposite to the first lateral surface 110 or the semiconductor package 200. As already described above in conjunction with FIG. 1, the at least one MUT 120 is configured to emit ultrasonic waves in the direction of the first lateral surface 111 and/or receive ultrasonic waves through the first lateral surface 111. In other words: The contact 251 of the lead frame 150 is bent away from the active sides of the semiconductor package 200 in order to form an electrical plug contact as the cable interface 130 on a rear side of the semiconductor package 200.

Precisely one contact 251 of the lead frame 150 is led out of the housing 110 in FIG. 2. However, it is to be noted that the semiconductor package 200 is not restricted thereto. In general, an arbitrary number M≥1 of contacts of the lead frame 150 can be led out of the housing 110. In other words: Multiple contacts of the lead frame 150 can optionally also be led out of the housing 110 in order to form respective electrical plug contacts for one or more plug connectors of one or more cables.

The semiconductor package 200 and the cable 160 form an ultrasound system 299.

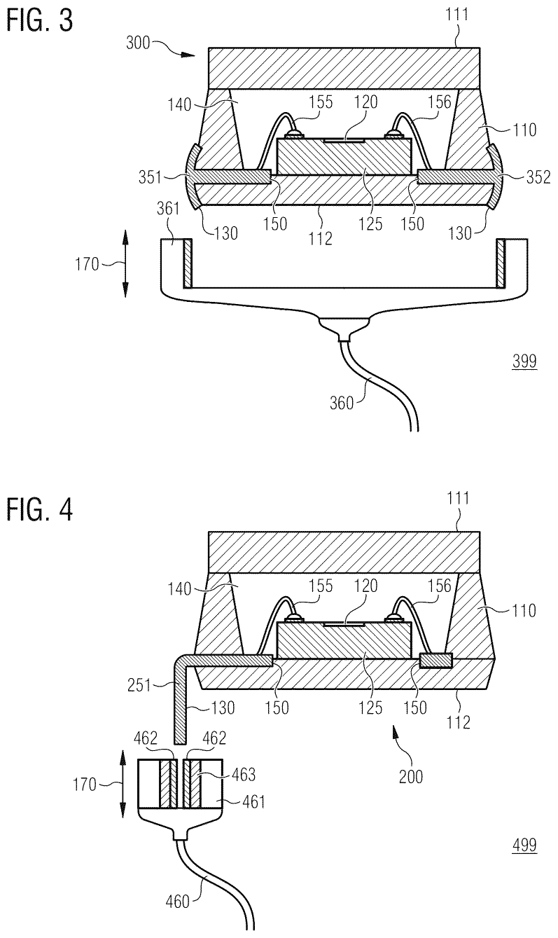

FIG. 3 schematically shows a sectional view of a third semiconductor package 300, in which multiple contacts of the lead frame are led to the outside. Otherwise, the semiconductor package 300 is embodied like the semiconductor package 100.

In FIG. 3, at least two contacts 351 and 352 of the lead frame 150 are led laterally out of the housing 110 on opposite sides and form electrical contact surfaces as the cable interface 130 on the laterally opposite sides of the housing 110. The at least two contacts 351 and 352 of the lead frame 150 are bent here such that they form convex electrical contact surfaces on the laterally opposite sides of the housing 110 as the cable interface 130.

However, it is to be noted that the present disclosure is not restricted to the formation of the at least two contacts 351 and 352 of the lead frame 150 shown in FIG. 3 in order to form electrical contact surfaces as the cable interface 130 on the laterally opposite sides of the housing 110. For example, the at least two contacts 351 and 352 of the lead frame 150 can be bent or formed only in the direction of the first lateral surface 111 (e.g., in the direction of the active side of the semiconductor package 300) or only in the direction of the second lateral surface 112 (e.g., in the direction of the rear side of the semiconductor package 300). Alternatively, one or more contacts of the at least two contacts 351 and 352 of the lead frame 150 can be bent in the direction of the first lateral surface 111 and one or more other contacts of the at least two contacts 351 and 352 of the lead frame 150 can be bent in the direction of the second lateral surface 112.

In comparison to the plug connector 161 of the cable 160 shown in FIG. 1 and FIG. 2, the plug connector 361 of the cable 360 shown in FIG. 3 is adapted with respect to its dimensions so that it overlaps the electrical contact surfaces formed on the laterally opposite sides of the housing 110 and thus can electrically contact the at least two contacts 351 and 352 of the lead frame 150.

The semiconductor package 300 and the cable 360 form an ultrasound system 399.

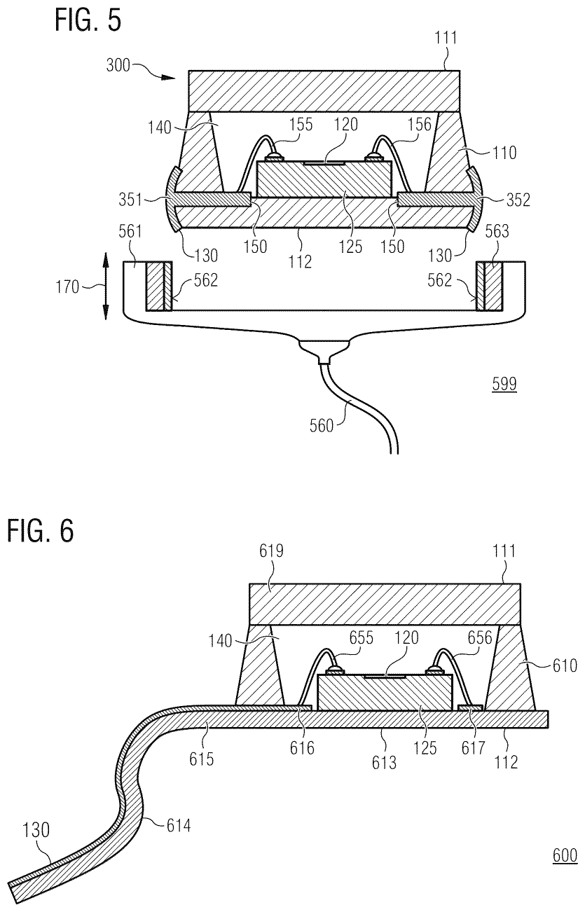

In diverse applications, acoustic decoupling of the semiconductor package and the cable can be desirable. In order to achieve the acoustic decoupling of the semiconductor package and the cable, the plug connector of the cable can comprise an acoustic decoupling medium for acoustically decoupling the cable interface of the semiconductor package and the plug connector in the connected state of the cable interface and the plug connector. This is shown hereinafter by way of example based on FIG. 4 and FIG. 5. It is self-evident that accordingly the plug connector configured in conjunction with the rules described in FIG. 4 and FIG. 5 can also be used together with the other semiconductor packages described herein.

FIG. 4 shows a further ultrasound system 499. The ultrasound system 499 comprises the semiconductor package 200 described above in conjunction with FIG. 2 and also a cable 460, which is connectable to the cable interface 130 of the semiconductor package 200.

In comparison to the plug connector 161 of the cable 160 shown in FIG. 2, the plug connector 461 of the cable 460 comprises, in addition to the electrical contact surfaces 462 for the electrical contacting of the cable interface 130 integrated into the housing 110, an acoustic decoupling medium 463 for acoustically decoupling the cable interface 130 and the plug connector 461 in the connected state of the cable interface 130 and the plug connector 461.

The acoustic decoupling medium 463 is a substance or a material which reduces or prevents the transmission of ultrasonic waves between the cable interface 130 and the remainder of the plug connector 461 in the connected state of the cable interface 130 and the plug connector 461. The acoustic decoupling medium 463 is used as a medium through which the ultrasonic waves can only propagate poorly in order to ensure that a high or maximum energy loss results when the ultrasonic waves pass over from the cable interface 130 to the plug connector 461 and vice versa. The acoustic decoupling medium 463 can be a (very) soft material in comparison to the other materials of the plug connector 461 and the cable interface 130 in order to dissipate acoustic stress between the cable interface 130 and the remainder of the plug connector 461. For example, the acoustic decoupling medium 463 can be formed from or comprise a vulcanized rubber, another rubber-like material, a silicone, or an acrylate. However, the present disclosure is not restricted to the above-mentioned substances. In general, any suitable substance can be used for the acoustic decoupling medium 463. The composition of the acoustic decoupling medium 463 can depend, for example, on the specific application and thus on the frequency range of the ultrasonic waves emitted and/or to be detected by the at least one MUT 120.

The semiconductor package 200 can be acoustically decoupled from the cable 460 by the acoustic decoupling medium 463. Accordingly, a transmission of ultrasonic waves from the semiconductor package 200 via the cable 460 to external entities connected to the other end of the cable 460 can be prevented or at least (strongly) reduced and vice versa.

In FIG. 4, the electrical contact surfaces 462 and the acoustic decoupling medium 463 of the plug connector 461 are shown as separate elements. However, the present disclosure is not restricted thereto. In alternative examples, the electrical contact surfaces 462 and the acoustic decoupling medium 463 of the plug connector 461 can be embodied integrally. For example, in a plug connector according to the present disclosure, the acoustic decoupling medium can be electrically conductive or mixed with an electrically conductive material so that the acoustic decoupling medium can be used simultaneously as the electrical contact surface(s) for the electrical contacting of the cable interface 130 integrated into the housing 110. For example, a rubber material admixed with carbon can be used for the integral implementation.

FIG. 5 shows a further ultrasound system 599. The ultrasound system 599 comprises the semiconductor package 300 described above in conjunction with FIG. 3 and also a cable 560, which is connectable to the cable interface 130 of the semiconductor package 300.

In comparison to the plug connector 361 of the cable 360 shown in FIG. 3, the plug connector 561 of the cable 560 comprises, in addition to the electrical contact surfaces 562 for the electrical contacting of the cable interface 130 integrated into the housing 110, an acoustic decoupling medium 563 for acoustically decoupling the cable interface 130 and the plug connector 561 in the connected state of the cable interface 130 and the plug connector 561.

The semiconductor package 300 can be acoustically decoupled from the cable 560 by the acoustic decoupling medium 563—similarly to the above statements with respect to the ultrasound system 499.

In the examples described above in conjunction with FIG. 1 to FIG. 5, in each case a lead frame 150 is arranged in the housing 110 and electrically coupled with the at least one MUT 120. Moreover, at least one contact of the lead frame 150 is led out of the housing 110 in each case in order to form the cable interface 130. This enables cost-effective production, since only one or more contacts of the lead frame 150 have to be correspondingly formed or bent for the formation of the cable interface 130. Moreover, no reflow processes are necessary for the production, so that the respective semiconductor package also does not have to be subjected to the high temperatures of the reflow process. This permits a high level of flexibility in the selection of the materials for the individual components of the respective semiconductor package and can increase the reliability of the individual components of the respective semiconductor package.

However, the present disclosure is not restricted thereto. Further examples with alternative implementations of the housing or the cable interface integrated into the housing are described hereinafter with reference to FIG. 6 to FIG. 9. In the following description, essentially only the differences from the above-described examples are discussed in order to avoid unnecessary repetitions.

FIG. 6 shows a further semiconductor package 600. In contrast to the semiconductor packages 100 to 500, the housing 610 of the semiconductor package 600 is not completely formed from potting compound (potting material). A part of the housing 610 is formed by a flexible circuit board 615. The flexible circuit board 615 is produced from a flexible substrate such as polyimide or polyester, so that it may be bent and rotated—as indicated by the twisted shape of the flexible circuit board 615 in FIG. 6. One or more electrically conductive structures 616 and 617 made of electrically conductive material such as one or more conductor tracks are formed on the flexible circuit board 615. Flexible circuit boards are also known under the designation “flex PCB”.

The at least one MUT 120 or the semiconductor material 125 in which the at least one MUT 120 is formed is arranged on a first area 613 of the flexible circuit board 615 and electrically coupled thereto. For this purpose, the at least one MUT 120 is electrically contacted using one or more bond wires—as indicated in FIG. 6 by the bond wires 655 and 656 between the semiconductor material 125 and the electrically conductive structures 616 and 617.

The first area 613 of the flexible circuit board 615 is surrounded by the remaining part 619 of the housing 610. The remaining housing 619 of the semiconductor package 600 is formed as in the above examples from potting compound (potting material). The remaining housing 619 made of potting compound is formed on the flexible circuit board 615. In the housing 610, similarly to the above examples, an acoustic coupling medium 140 for acoustically coupling the at least one MUT 120 to the housing 610 is arranged (introduced).

A second area 614 of the flexible circuit board 615, which is different from the first area 613 and in which the one or more electrically conductive structures 616 and 617 are formed, forms an electrical plug contact as the cable interface 130. In other words: A part of the flexible circuit board 615, on which the at least one MUT 120 and the remaining housing 619 of the semiconductor package 600 are not formed, forms the cable interface 130. Accordingly, the semiconductor package 600 can be separably connected to a plug connector of a cable, similarly to the above implementations, in order to externally electrically contact the semiconductor package 600. The one or more electrically conductive structures 616 and 617 can extend in the second area 614 of the flexible circuit board 615, for example, essentially linearly and parallel to one another, so that conventional plug connectors can be used for the contacting.

Since the semiconductor package 600 can also follow curved surfaces due to the flexible circuit board 615, the installation of the semiconductor package 600 in an application can be simplified.

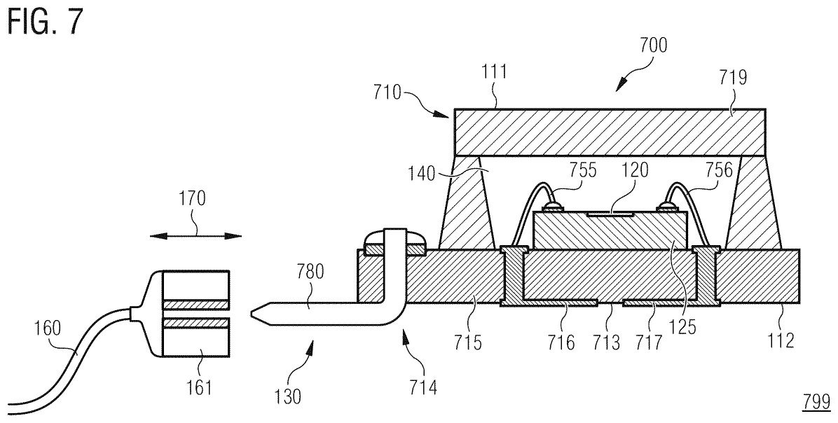

In the semiconductor package 700 shown in FIG. 7, the at least one MUT 120 or the semiconductor material 125 in which the at least one MUT 120 is formed is also arranged on a first area 713 of a circuit board 715 and electrically coupled thereto. In contrast to the semiconductor package 600, however, the circuit board 715 is a rigid circuit board and not a flexible circuit board.

Similarly to the example of FIG. 6, the at least one MUT 120 is electrically contacted using one or more bond wires—as indicated in FIG. 7 by the bond wires 755 and 756 between the semiconductor material 125 and electrically conductive structures 716 and 717 of the circuit board 715 made of electrically conductive material.

The first area 713 of the circuit board 715 is again surrounded by the remaining part 719 of the housing 710. The remaining housing 719 of the semiconductor package 700 is formed as in the above examples from potting compound (potting material). In the housing 710, similarly to the above examples, an acoustic coupling medium 740 for acoustically coupling the at least one MUT 120 to the housing 710 is arranged (introduced).

In a second area 714 of the circuit board 715, which is different from the first area 713, an electrical plug contact 780 is arranged on the circuit board 715 as the cable interface 130. The electrical plug contact 780 is electrically coupled via the one or more electrically conductive structures 716 and 717 of the circuit board 715 with the at least one MUT 120 or the semiconductor material 125 (and possibly to further electrical elements or components of the semiconductor package 700). For example, the plug contact 780 can be electrically coupled via a corresponding metallization (such as solder material) with the one or more electrically conductive structures 716 and 717 of the circuit board 715.

In the example of FIG. 7, the electrical plug contact 780 is bent to form a laterally extending electrical plug contact as the cable interface 130. However, it is to be noted that the present disclosure is not restricted thereto. For example, the electrical plug contact 780 can also extend exclusively in the direction from the first lateral surface 111 to the second lateral surface 112 of the housing 710 or the semiconductor package 700. In other words: The electrical plug contact 780 can form the cable interface 130 on the rear side of the semiconductor package 700.

Precisely one plug contact 780 is shown in FIG. 7. However, it is to be noted that the semiconductor package 700 is not restricted thereto. In general, an arbitrary number K≥1 of plug contacts can be arranged in the second area 714 of the circuit board 715. In other words: Multiple plug contacts can optionally also be arranged in the second area 714 of the circuit board 715 to form the cable interface 130. As indicated in FIG. 7 by the arrow 170, the plug connector 161 of the cable 160 is separably connected to the cable interface 130 integrated into the housing 110 of the semiconductor package 100, e.g., the at least one plug contact 780, in order to electrically contact the semiconductor package 700 using the cable 160.

The semiconductor package 700 and the cable 160 form an ultrasound system 799.

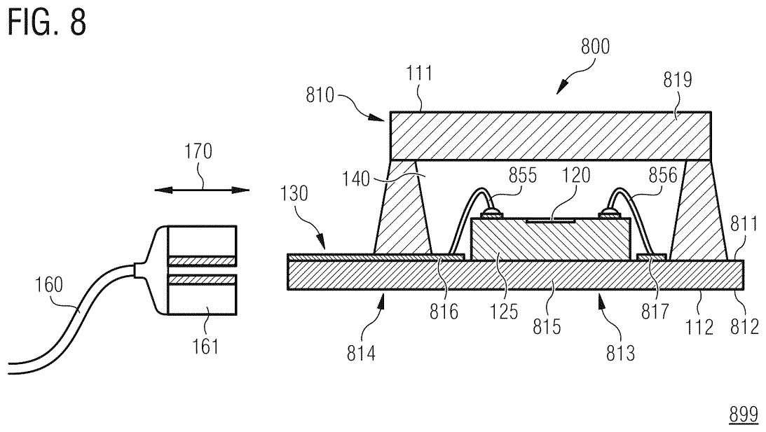

FIG. 8 shows a further semiconductor package 800, in which a part of the housing 810 is formed by a rigid substrate or a rigid carrier 815. The rigid substrate 815 can be formed, for example, from a plastic. However, it is to be noted that the present disclosure is not restricted thereto. In principle, any suitable material can be used for the rigid substrate 815.

The at least one MUT 120 or the semiconductor material 125 in which the at least one MUT 120 is formed is arranged on a first area 813 of the rigid substrate 815 and is electrically coupled thereto. Similarly to the above examples, the at least one MUT 120 is electrically contacted using one or more bond wires—as indicated in FIG. 8 by the bond wires 855 and 856 between the semiconductor material 125 and electrically conductive structures 816 and 817 made of electrically conductive material in or on the rigid substrate 815.

The first area 813 of the rigid substrate 815 is surrounded by the remaining part 819 of the housing 810—similarly as in the examples described in conjunction with FIG. 6 and FIG. 7. The remaining housing 819 of the semiconductor package 800 is formed as in the above examples from potting compound (potting material). In the housing 810, similarly to the above examples, an acoustic coupling medium 140 for acoustically coupling the at least one MUT 120 to the housing 810 is arranged (introduced).

A second area 814 of the substrate 815, which is different from the first area 813 and in which the one or more electrically conductive structures 816 and 817 are formed, forms an electrical plug contact as the cable interface 130. In other words: A part of the substrate 815 on which the at least one MUT 120 and the remaining housing 819 of the semiconductor package 800 are not formed forms the cable interface 130. Accordingly, the semiconductor package 800 can be separably connected to a plug connector of a cable, similarly to the above implementations, in order to externally electrically contact the semiconductor package 800. The one or more electrically conductive structures 816 and 817 can extend, for example, essentially linearly and parallel to one another in the second area 814 of the substrate 815, so that the cable interface 130 is formed similarly to the electrical contacts of an SD memory card and therefore conventional plug connectors can be used for the contacting.

The at least one MUT 120 or the semiconductor material 125 in which the at least one MUT 120 is formed is arranged on a first side 811 of the substrate 815. The one or more electrically conductive structures 816 and 817 or the partial areas thereof which form the cable interface 130 can be formed exclusively on the first side 811 of the substrate 815—as shown in FIG. 8.

Alternatively, the one or more electrically conductive structures 816 and 817 or the partial areas thereof which form the cable interface 130 can also be formed exclusively on a second side 812 of the substrate, which is opposite to the first side 811 of the substrate 815. Furthermore, the one or more electrically conductive structures 816 and 817 or the partial areas thereof which form the cable interface 130 can be arranged both on the first side 811 and on the second side 812 of the substrate 815.

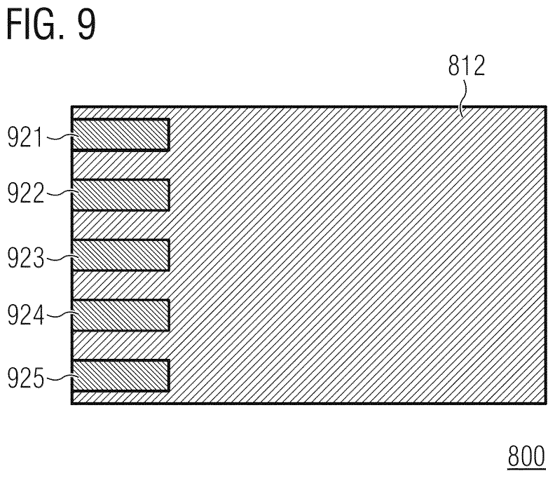

FIG. 9 shows an example top view of the second side 812 of the substrate 815. The five electrically conductive structures 921, . . . , 925 extending parallel to one another are to be understood solely as examples. Both on the first side 811 and on the second side 812 of the substrate 815, in principle any number of electrically conductive structures can be provided to form the cable interface 130. The respective electrically conductive structures on each side of the substrate 815 can in particular extend linearly and parallel to one another so that the cable interface 130 is formed similarly to the electrical contacts of an SD memory card.

The semiconductor package 800 and the cable 160 form an ultrasound system 899.

All of the above-described semiconductor packages 100 to 800 share the feature that they comprise a housing and at least one MUT arranged in the housing. Furthermore, each of the semiconductor packages 100 to 800 comprises a cable interface integrated into the housing, which is configured to be separably connected to a plug connector of a cable in order to externally electrically contact the semiconductor package. As the above statements have shown, the cable interface integrated into the housing can be embodied in a variety of ways. Independently of the specific implementation of the integrated cable interface, this enables the flexible and simple installation of cables in order to electrically contact the at least one MUT. The semiconductor package or the at least one MUT can accordingly also be integrated into very small systems. The semiconductor packages 100 to 800 can also enable a simplified installation in applications and thus reduce the system costs of the application. In particular, an extra circuit board provided for this purpose is not necessary for the installation of any of the semiconductor packages 100 to 800. Rather, a semiconductor package according to the present disclosure can be connected via a corresponding cable to arbitrary further elements. It can therefore be sufficient, for example, to provide a circuit board for an application using which both a semiconductor package according to the present disclosure can be electrically coupled via a corresponding cable and also other components of the application can be electrically coupled.

### ASPECTS

Aspects of the present disclosure provide a micromechanical ultrasonic transducer component having integrated cable interface.

The aspects described here may be summarized as follows:

Aspect 1 is a semiconductor package. The semiconductor package comprises a housing and at least one micromechanical ultrasonic transducer arranged in the housing. Furthermore, the semiconductor package comprises a cable interface integrated into the housing, which is configured to be separably connected to a plug connector in order to electrically contact the semiconductor package externally.

Aspect 2 is the semiconductor package according to Aspect 1, wherein a lead frame is arranged in the housing and is electrically coupled to the at least one micromechanical ultrasonic transducer, and wherein at least one contact of the lead frame is led out of the housing to form the cable interface.

Aspect 3 is the semiconductor package according to Aspect 2, wherein the at least one contact of the lead frame protrudes laterally out of the housing in order to form a respective laterally extending electrical plug contact as the cable interface.

Aspect 4 is the semiconductor package according to Aspect 2, wherein the at least one contact of the lead frame protrudes laterally out of the housing and is bent in the direction of a second lateral surface of the semiconductor package in order to form a respective electrical plug contact as the cable interface, wherein the second lateral surface is opposite to a first lateral surface of the semiconductor package, and wherein the at least one micromechanical ultrasonic transducer is configured to emit ultrasonic waves in the direction of the first lateral surface and/or to receive ultrasonic waves through the first lateral surface.

Aspect 5 is the semiconductor package according to Aspect 2, wherein at least two contacts of the lead frame are led laterally out of the housing on opposite sides and form electrical contact surfaces on the laterally opposite sides of the housing as the cable interface.

Aspect 6 is the semiconductor package according to Aspect 5, wherein the at least two contacts of the lead frame are bent such that they form convex electrical contact surfaces on the laterally opposite sides of the housing as the cable interface.

Aspect 7 is the semiconductor package according to Aspect 1, wherein a part of the housing is formed by a flexible circuit board, wherein the at least one micromechanical ultrasonic transducer is arranged on a first area of the flexible circuit board and is electrically coupled thereto, and wherein a second area of the flexible circuit board, which is different from the first area and in which one or more electrically conductive structures are formed, forms an electrical plug contact as the cable interface.

Aspect 8 is the semiconductor package according to Aspect 1, wherein a part of the housing is formed by a circuit board, wherein the at least one micromechanical ultrasonic transducer is arranged on a first area of the circuit board and is electrically coupled thereto, and wherein at least one electrical plug contact is arranged on the circuit board as the cable interface in a second area of the circuit board different from the first area.

Aspect 9 is the semiconductor package according to Aspect 8, wherein the at least one electrical plug contact is bent to form a respective laterally extending electrical plug contact as the cable interface.

Aspect 10 is the semiconductor package according to Aspect 1, wherein a part of the housing is formed by a rigid substrate, wherein the at least one micromechanical ultrasonic transducer is arranged on a first area of the substrate and is electrically coupled thereto, and wherein a second area of the substrate, which is different from the first area and in which one or more electrically conductive structures are formed, forms an electrical plug contact as the cable interface.

Aspect 11 is the semiconductor package according to Aspect 10, wherein the at least one micromechanical ultrasonic transducer is arranged on a first side of the substrate, wherein the first side is opposite to a second side of the substrate and wherein the one or more electrically conductive structures are formed on the first side and/or the second side of the substrate.

Aspect 12 is the semiconductor package according to any one of Aspects 7 to 11, wherein the first area is surrounded by the remaining housing of the semiconductor package.

Aspect 13 is the semiconductor package according to any one of Aspects 1 to 12, wherein an acoustic coupling medium for acoustically coupling the at least one micromechanical ultrasonic transducer with the housing is arranged in the housing.

Aspect 14 is the semiconductor package according to any one of Aspects 1 to 13, wherein multiple micromechanical ultrasonic transducers are arranged in the housing.

Aspect 15 is the semiconductor package according to any one of Aspects 1 to 14, wherein the at least one micromechanical ultrasonic transducer is electrically contacted using one or more bond wires.

Aspect 16 is the semiconductor package according to any one of Aspects 1 to 15, wherein the at least one micromechanical ultrasonic transducer is a capacitive micromechanical ultrasonic transducer or a piezoelectric micromechanical ultrasonic transducer.

Aspect 17 is the semiconductor package according to any one of Aspects 1 to 16, wherein the housing is at least partially formed from potting compound.

Aspect 18 is an ultrasound system. The ultrasound system comprises a semiconductor package according to any one of Aspects 1 to 17 and a cable having a plug connector. The plug connector is separably connectable to the cable interface integrated into the housing of the semiconductor package in order to electrically contact the semiconductor package using the cable.

Aspect 19 is the ultrasound system according to Aspect 18, wherein the plug connector comprises an acoustic decoupling medium for acoustically decoupling the cable interface and the plug connector in the connected state of the cable interface and the plug connector.

Aspect 20 is the ultrasound system according to Aspect 19, wherein the acoustic decoupling medium is electrically conductive or is mixed with electrically conductive material.

The aspects and features described in connection with a particular one of the previous aspects may also be combined with one or more of the other aspects to replace an identical or similar feature of this other aspect or to introduce the feature additionally into the other aspect.

The following claims are hereby incorporated into the detailed description, each claim being independent as a separate aspect. It should also be noted that—although a dependent claim in the claims refers to a particular combination with one or more other claims—other aspects may also comprise a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A semiconductor package, comprising:
a housing;
at least one micromechanical ultrasonic transducer arranged in the housing; and
a cable interface, which is integrated into the housing and is configured to be separably connected to a plug connector of a cable in order to externally electrically contact the semiconductor package.

2. The semiconductor package as claimed in claim 1, further comprising:
a lead frame arranged in the housing and electrically coupled to the at least one micromechanical ultrasonic transducer,
wherein at least one contact of the lead frame is led out of the housing to form the cable interface.

3. The semiconductor package as claimed in claim 2, wherein the at least one contact of the lead frame protrudes laterally out of the housing to form a respective laterally extending electrical plug contact as the cable interface.

4. The semiconductor package as claimed in claim 2,
wherein the at least one contact of the lead frame protrudes laterally out of the housing and is bent in a direction of a second lateral surface of the semiconductor package to form a respective electrical plug contact as the cable interface,
wherein the second lateral surface is arranged opposite to a first lateral surface of the semiconductor package, and
wherein the at least one micromechanical ultrasonic transducer is configured to at least one of emit ultrasonic waves in a direction of the first lateral surface or receive ultrasonic waves through the first lateral surface.

5. The semiconductor package as claimed in claim 2, wherein at least two contacts of the lead frame are led laterally out of the housing on laterally opposite sides of the housing and form electrical contact surfaces on the laterally opposite sides of the housing as the cable interface.

6. The semiconductor package as claimed in claim 5, wherein the at least two contacts of the lead frame are bent such that the at least two contacts form convex electrical contact surfaces on the laterally opposite sides of the housing as the cable interface.

7. The semiconductor package as claimed in claim 1,
wherein a part of the housing is formed by a flexible circuit board,
wherein the at least one micromechanical ultrasonic transducer is arranged on a first area of the flexible circuit board and is electrically coupled to the first area of the flexible circuit board, and
wherein a second area of the flexible circuit board, which is different from the first area and in which one or more electrically conductive structures are formed, forms an electrical plug contact as the cable interface.

8. The semiconductor package as claimed in claim 1,
wherein a part of the housing is formed by a circuit board,
wherein the at least one micromechanical ultrasonic transducer is arranged on a first area of the circuit board and is electrically coupled to first area of the flexible circuit board, and
wherein at least one electrical plug contact is arranged on the circuit board as the cable interface in a second area of the circuit board, which is different from the first area.

9. The semiconductor package as claimed in claim 8, wherein the at least one electrical plug contact is bent to form a respective laterally extending electrical plug contact as the cable interface.

10. The semiconductor package as claimed in claim 1,
wherein a part of the housing is formed by a rigid substrate,
wherein the at least one micromechanical ultrasonic transducer is arranged on a first area of the rigid substrate and is electrically coupled to the first area of the rigid substrate, and
wherein a second area of the rigid substrate, which is different from the first area and in which one or more electrically conductive structures are formed, forms an electrical plug contact as the cable interface.

11. The semiconductor package as claimed in claim 10,
wherein the at least one micromechanical ultrasonic transducer is arranged on a first side of the rigid substrate,
wherein the first side is arranged opposite to a second side of the rigid substrate and
wherein the one or more electrically conductive structures are formed on at least one of the first side or the second side of the rigid substrate.

12. The semiconductor package as claimed in claim 7, wherein the first area is surrounded by a remaining housing of the semiconductor package.

13. The semiconductor package as claimed in claim 1, wherein an acoustic coupling medium for acoustically coupling the at least one micromechanical ultrasonic transducer with the housing is arranged in the housing.

14. The semiconductor package as claimed in claim 1, wherein the at least one micromechanical ultrasonic transducer includes multiple micromechanical ultrasonic transducers, which are arranged in the housing.

15. The semiconductor package as claimed in claim 1, wherein the at least one micromechanical ultrasonic transducer is electrically contacted using one or more bond wires.

16. The semiconductor package as claimed in claim 1, wherein the at least one micromechanical ultrasonic transducer is a capacitive micromechanical ultrasonic transducer or a piezoelectric micromechanical ultrasonic transducer.

17. The semiconductor package as claimed in claim 1, wherein the housing is at least partially formed from potting compound.

18. An ultrasound system, comprising:
a semiconductor package comprising:
a housing;
at least one micromechanical ultrasonic transducer arranged in the housing; and
a cable interface, which is integrated into the housing and is configured to be separably connected to a plug connector of a cable in order to externally electrically contact the semiconductor package; and
a cable having the plug connector, wherein the plug connector is separably connectable to the cable interface integrated into the housing of the semiconductor package in order to electrically contact the semiconductor package using the cable.

19. The ultrasound system as claimed in claim 18, wherein the plug connector comprises an acoustic decoupling medium for acoustically decoupling the cable interface and the plug connector in a connected state of the cable interface and the plug connector.

20. The ultrasound system as claimed in claim 19, wherein the acoustic decoupling medium is electrically conductive or is mixed with an electrically conductive material.
